(19) United States
(12) Patent Application Publication
(10) Pub. No.: US 2006/0131565 A1
(43) Pub. Date: Jun. 22, 2006

(54) Surface modified electrodes for electrooptic devices

(75) Inventors: Larry Neil Lewis, Scotia, NY (US); Kyle Erik Litz, Ballston Spa, NY (US); Jie Liu, Niskayuna, NY (US); James Anthony Cella, Clifton Park, NY (US); Joseph John Shiang, Niskayuna, NY (US); Tami Janene Faircloth, Niskayuna, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: General Electric Company

(21) Appl. No.: 11/017,473

(22) Filed: Dec. 20, 2004

(51) Int. Cl. H01B 1/12; H01L 51/50; H05B 33/26

(52) U.S. Cl. 257/40; 428/411.1; 428/690; 428/917; 428/447; 252/500; 313/503

(57) ABSTRACT

A surface modified electrode comprising at least one conductive layer, and at least one reduced polymeric material, wherein the reduced polymeric material comprises at least one additional electron relative to a corresponding neutral polymeric precursor; and at least one cationic species is provided. Coating compositions and coated articles comprising the reduced polymeric materials are also provided. The coating compositions lower the work function of the electrode surface, thereby facilitating the production of more efficient electrooptic devices.

### BACKGROUND OF THE INVENTION

This invention relates to a surface modified electrode comprising a reduced polymeric species. Further, the invention relates to a coating composition suitable for producing the surface modified electrode; and electrooptic devices comprising such surface modified electrodes.

Efficient operation of electronic devices depends, among other things, efficient transport of charges between an electrode and an adjacent medium. Opto-electronic devices comprise a class of electronic devices and are currently used in several applications that incorporate the principle of conversion between optical energy and electrical energy. Electroluminescent (“EL”) devices, which are one type of such devices, may be classified as either organic or inorganic and are well known in graphic display and imaging art. EL devices have been produced in different shapes for many applications. Inorganic EL devices, however, typically suffer from a required high activation voltage and low brightness. On the other hand, organic EL devices (“OELDs”), which have been developed more recently, offer the benefits of lower activation voltage and higher brightness in addition to simple manufacture, and, thus, the promise of more widespread applications.

An OELD is typically a thin film structure formed on a substrate such as glass or plastic. A light-emitting layer of an organic EL material and optional adjacent organic semiconductor layers are sandwiched between a cathode and an anode. The organic semiconductor layers may be either hole (positive charge)-injecting or electron (negative charge)-injecting layers and also comprise organic materials. The material for the light-emitting layer may be selected from many organic EL materials that emit light having different wavelengths. The light-emitting organic layer may itself consist of multiple sublayers, each comprising a different organic EL material. State-of-the-art organic EL materials can emit electromagnetic (“EM”) radiation having narrow ranges of wavelengths in the visible spectrum. Unless specifically stated, the terms “EM radiation” and “light” are used interchangeably in this disclosure to mean generally radiation having wavelengths in the range from ultraviolet (“UV”) to mid-infrared (“mid-IR”) or, in other words, wavelengths in the range from about 300 nanometers to about 10 micrometers.

Reducing or eliminating barriers for charge injection between the organic EL layer and an electrode contributes greatly to enhance the device efficiency. Metals having low work functions, such as the alkali and alkaline-earth metals, are often used in a cathode material to promote electron injection. However, these metals are susceptible to degradation upon exposure to the environment. Therefore, devices using these metals as cathode materials require rigorous encapsulation.

Other opto-electronic devices, such as photovoltaic cells, can also benefit from a lower barrier for electron transport across the interface between an active layer and an adjacent cathode.

Therefore, it is desirable to provide materials that lower the injection barrier, thereby allowing for efficient charge flow between the electrodes and an adjacent material and, at the same time, substantially preserve the long-term stability of the device.

### BRIEF SUMMARY OF THE INVENTION

In one aspect the present invention provides a surface modified electrode comprising (a) at least one conductive layer; and (b) at least one reduced organic material, said reduced organic material comprising at least one additional electron relative to a corresponding neutral polymeric precursor and at least one cationic species.

In another aspect, the invention provides a surface modified electrode comprising (a) at least one conductive layer, and (b) at least one reduced polymeric material, wherein the reduced polymeric material comprises at least one additional electron relative to a corresponding neutral polymeric precursor, and at least one cationic species.

Another aspect of the invention is a coating composition comprising at least one reduced polymeric material, where the reduced polymeric material comprises at least one additional electron relative to a corresponding neutral polymeric precursor, and at least one cationic species; and at least one polar aprotic solvent.

Yet another aspect of the invention is an electrooptic device comprising a surface modified first electrode; a second eletrode; and an electroluminescent organic material disposed between the first electrode and the second electrode; wherein the surface modified first electrode comprises at least one conductive layer, and at least one reduced polymeric material, said reduced polymeric material comprising at least one additional electron relative to a corresponding neutral polymeric precursor and at least one cationic species.

Other features and advantages of the present invention will be apparent from a perusal of the following detailed description of the invention.

### DETAILED DESCRIPTION OF THE INVENTION

The present invention may be understood more readily by reference to the following detailed description of preferred embodiments of the invention and the examples included therein. In the following specification and the claims which follow, reference will be made to a number of terms which shall be defined to have the following meanings:

The singular forms “a”, “an” and “the” include plural referents unless the context clearly dictates otherwise.

“Optional” or “optionally” means that the subsequently described event or circumstance may or may not occur, and that the description includes instances where the event occurs and instances where it does not.

As used herein the term “aliphatic radical” refers to an organic radical having a valence of at least one comprising a linear or branched array of atoms which is not cyclic. Aliphatic radicals are defined to comprise at least one carbon atom. The array of atoms comprising the aliphatic radical may include heteroatoms such as nitrogen, sulfur, silicon, selenium and oxygen or may be composed exclusively of carbon and hydrogen. For convenience, the term “aliphatic radical” is defined herein to encompass, as part of the “linear or branched array of atoms which is not cyclic” a wide range of functional groups such as alkyl groups, alkenyl groups, alkynyl groups, halo alkyl groups, conjugated dienyl groups, alcohol groups, ether groups, aldehyde groups, ketone groups, carboxylic acid groups, acyl groups (for example carboxylic acid derivatives such as esters and amides), amine groups, nitro groups and the like. For example, the 4-methylpent-1-yl radical is a C₆ aliphatic radical comprising a methyl group, the methyl group being a functional group which is an alkyl group. Similarly, the 4-nitrobut-1-yl group is a C₄ aliphatic radical comprising a nitro group, the nitro group being a functional group. An aliphatic radical may be a haloalkyl group which comprises one or more halogen atoms which may be the same or different. Halogen atoms include, for example; fluorine, chlorine, bromine, and iodine. Aliphatic radicals comprising one or more halogen atoms include the alkyl halides trifluoromethyl, bromodifluoromethyl, chlorodifluoromethyl, hexafluoroisopropylidene, chloromethyl; difluorovinylidene; trichloromethyl, bromodichloromethyl, bromoethyl, 2-bromotrimethylene (e.g.—CH₂CHBrCH₂—), and the like. Further examples of aliphatic radicals include allyl, aminocarbonyl (i.e.—CONH₂), carbonyl, dicyanoisopropylidene (i.e.—CH₂C(CN)₂CH₂—), methyl (i.e.—CH₃), methylene (i.e.—CH₂—), ethyl, ethylene, formyl (i.e.—CHO), hexyl, hexamethylene, hydroxymethyl (i.e.—CH₂OH), mercaptomethyl (i.e.—CH₂SH), methylthio (i.e.—SCH₃), methylthiomethyl (i.e.—CH₂SCH₃), methoxy, methoxycarbonyl (i.e. CH₃OCO—), nitromethyl (i.e.—CH₂NO₂), thiocarbonyl, trimethylsilyl (i.e. (CH₃)₃Si—), t-butyldimethylsilyl, trimethyoxysilypropyl (i.e. (CH₃O)₃SiCH₂CH₂CH₂—), vinyl, vinylidene, and the like. By way of further example, a C₁-C₁₀ aliphatic radical contains at least one but no more than 10 carbon atoms. A methyl group (i.e. CH₃—) is an example of a C₁ aliphatic radical. A decyl group (i.e. CH₃(CH₂)₁₀—) is an example of a C₁₀ aliphatic radical.

As used herein, the term “aromatic radical” refers to an array of atoms having a valence of at least one comprising at least one aromatic group. The array of atoms having a valence of at least one comprising at least one aromatic group may include heteroatoms such as nitrogen, sulfur, selenium, silicon and oxygen, or may be composed exclusively of carbon and hydrogen. As used herein, the term “aromatic radical” includes but is not limited to phenyl, pyridyl, furanyl, thienyl, naphthyl, phenylene, and biphenyl radicals. As noted, the aromatic radical contains at least one aromatic group. The aromatic group is invariably a cyclic structure having 4 n+2 “delocalized” electrons where “n” is an integer equal to 1 or greater, as illustrated by phenyl groups (n=1), thienyl groups (n=1), furanyl groups (n=1), naphthyl groups (n=2), azulenyl groups (n=2), anthraceneyl groups (n=3) and the like. The aromatic radical may also include nonaromatic components. For example, a benzyl group is an aromatic radical which comprises a phenyl ring (the aromatic group) and a methylene group (the nonaromatic component). Similarly a tetrahydronaphthyl radical is an aromatic radical comprising an aromatic group (C₆H₃) fused to a nonaromatic component —(CH₂)₄—. For convenience, the term “aromatic radical” is defined herein to encompass a wide range of functional groups such as alkyl groups, alkenyl groups, alkynyl groups, haloalkyl groups, haloaromatic groups, conjugated dienyl groups, alcohol groups, ether groups, aldehydes groups, ketone groups, carboxylic acid groups, acyl groups (for example carboxylic acid derivatives such as esters and amides), amine groups, nitro groups, and the like. For example, the 4-methylphenyl radical is a C₇ aromatic radical comprising a methyl group, the methyl group being a functional group which is an alkyl group. Similarly, the 2-nitrophenyl group is a C₆ aromatic radical comprising a nitro group, the nitro group being a functional group. Aromatic radicals include halogenated aromatic radicals such as trifluoromethylphenyl, hexafluoroisopropylidenebis(4-phen-1-yloxy) (i.e.—OPhC(CF₃)₂PhO—), chloromethylphenyl; 3-trifluorovinyl-2-thienyl; 3-trichloromethylphen-1-yl (i.e. 3-CCl₃Ph—), 4(3-bromoprop-1-yl)phen-1-yl (i.e. BrCH₂CH₂CH₂Ph—), and the like. Further examples of aromatic radicals include 4-allyloxyphen-1-oxy, 4-aminophen-1-yl (i.e. H₂NPh—), 3-aminocarbonylphen-1-yl (i.e. NH₂COPh—), 4-benzoylphen-1-yl, dicyanoisopropylidenebis(4-phen-1-yloxy) (i.e.—OPhC(CN)₂PhO—), 3-methylphen-1-yl, methylenebis(phen-4-yloxy) (i.e.—OPhCH₂PhO—), 2-ethylphen-1-yl, phenylethenyl, 3-formyl-2-hienyl, 2-hexyl-5-furanyl; hexamethylene-1,6-bis(phen-4-yloxy) (i.e.—OPh(CH₂)₆PhO—); 4-hydroxymethylphen-1-yl (i.e. 4-HOCH₂PhO—), 4-mercaptomethylphen-1-yl (i.e. 4-HSCH₂Ph—), 4-methylthiophen-1-yl (i.e. 4-CH₃SPh—), 3-methoxyphen-1-yl, 2-methoxycarbonylphen-1-yloxy (e.g. methyl salicyl), 2-nitromethylphen-1-yl (i.e.—PhCH₂NO₂), 3-trimethylsilylphen-1-yl, 4-t-butyldimethylsilylphenl-1-yl, 4-vinylphen-1-yl, vinylidenebis(phenyl), and the like. The term “a C₃-C₁₀ aromatic radical” includes aromatic radicals containing at least three but no more than 10 carbon atoms. The aromatic radical 1-imidazolyl (C₃H₂N₂—) represents a C₃ aromatic radical. The benzyl radical (C₇H₈—) represents a C₇ aromatic radical.

As used herein the term “cycloaliphatic radical” refers to a radical having a valence of at least one, and comprising an array of atoms which is cyclic but which is not aromatic. As defined herein a “cycloaliphatic radical” does not contain an aromatic group. A “cycloaliphatic radical” may comprise one or more noncyclic components. For example, a cyclohexylmethyl group (C₆H₁₁CH₂—) is an cycloaliphatic radical which comprises a cyclohexyl ring (the array of atoms which is cyclic but which is not aromatic) and a methylene group (the noncyclic component). The cycloaliphatic radical may include heteroatoms such as nitrogen, sulfur, selenium, silicon and oxygen, or may be composed exclusively of carbon and hydrogen. For convenience, the term “cycloaliphatic radical” is defined herein to encompass a wide range of functional groups such as alkyl groups, alkenyl groups, alkynyl groups, halo alkyl groups, conjugated dienyl groups, alcohol groups, ether groups, aldehyde groups, ketone groups, carboxylic acid groups, acyl groups (for example carboxylic acid derivatives such as esters and amides), amine groups, nitro groups and the like. For example, the 4-methylcyclopent-1-yl radical is a C₆ cycloaliphatic radical comprising a methyl group, the methyl group being a functional group which is an alkyl group. Similarly, the 2-nitrocyclobut-1-yl radical is a C₄ cycloaliphatic radical comprising a nitro group, the nitro group being a functional group. A cycloaliphatic radical may comprise one or more halogen atoms which may be the same or different. Halogen atoms include, for example; fluorine, chlorine, bromine, and iodine. Cycloaliphatic radicals comprising one or more halogen atoms include 2-trifluoromethylcyclohex-1-yl, 4-bromodifluoromethylcyclooct-1-yl, 2-chlorodifluoromethylcyclohex-1-yl, hexafluoroisopropylidene2,2-bis (cyclohex-4-yl) (i.e. —C₆H₁₀C(CF₃)₂ C₆H₁₀—), 2-chloromethylcyclohex-1-yl; 3-difluoromethylenecyclohex-1-yl; 4-trichloromethylcyclohex-1-yloxy, 4-bromodichloromethylcyclohex-1-ylthio, 2-bromoethylcyclopent-1-yl, 2-bromopropylcyclohex-1-yloxy (e.g. CH₃CHBrCH₂C₆H₁₀—), and the like. Further examples of cycloaliphatic radicals include 4-allyloxycyclohex-1-yl, 4-aminocyclohex-1-yl (i.e. H₂C₆H₁₀—), 4-aminocarbonylcyclopent-1-yl (i.e. NH₂COC₅H₈—), 4-acetyloxycyclohex-1-yl, 2,2-dicyanoisopropylidenebis(cyclohex-4-yloxy) (i.e. —OC₆H₁₀C(CN)₂C₆H₁₀—), 3-methylcyclohex-1-yl, methylenebis(cyclohex-4-yloxy) (i.e.—OC₆H₁₀CH₂C₆H₁₀—), 1-ethylcyclobut-1-yl, cyclopropylethenyl, 3-formyl-2-terahydrofuranyl, 2-hexyl-5-tetrahydrofuranyl; hexamethylene-1,6-bis(cyclohex-4-yloxy) (i.e. —OC₆H₁₀(CH₂)₆C₆H₁₀—); 4-hydroxymethylcyclohex-1-yl (i.e. 4-HOCH₂C₆H₁₀), 4-mercaptomethylcyclohex-1-yl (i.e. 4-HSCH₂C₆H₁₀), 4-methylthiocyclohex-1-yl (i.e. 4-CH₃SC₆H₁₀—), 4-methoxycyclohex-1-yl, 2-methoxycarbonylcyclohex-1-yloxy (2-CH₃OCOC₆H₁₀—), 4-nitromethylcyclohex-1-yl (i.e. NO₂CH₂C₆H₁₀—), 3-trimethylsilylcyclohex-1-yl, 2-t-butyldimethylsilylcyclopent-1-yl, 4-trimethoxysilylethylcyclohex-1-yl (e.g. (CH₃O)₃SiCH₂CH₂C₆H₁₀—), 4-vinylcyclohexen-1-yl, vinylidenebis(cyclohexyl), and the like. The term “a C₃-C₁₀ cycloaliphatic radical” includes cycloaliphatic radicals containing at least three but no more than 10 carbon atoms. The cycloaliphatic radical 2-tetrahydrofuranyl (C₄H₇O—) represents a C₄ cycloaliphatic radical. The cyclohexylmethyl radical (C₆H₁₁CH₂—) represents a C₇ cycloaliphatic radical.

As used herein, the terms “optoelectronic device” and light-emitting device” are used interchangeably with the term “electrooptic device”; and are taken to mean a device which converts electrical energy into light energy.

As used herein, the term “reduced polymeric species comprising at least one additional electron” means a polymeric species resulting from the corresponding neutral polymeric precursor accepting one or more electrons from an electron donor. The reduced polymeric species is sometimes referred to as an “anionic species”. The reduced polymeric species comprises at least one of a radical anionic species, a dianionic species, or a combination of at least one radical anionic species and at least one dianionic species. For example, a polymeric species comprising pendant naphthyl and phenyl groups, upon acceptance of an electron can form a reduced polymeric species having a naphthyl radical anion, which upon accepting another electron can form a reduced polymeric species having a naphthyl dianion, or one naphthyl radical anion and one phenyl radical anion, and the like.

As used herein, the notation [symbol] as applied to the various structures for the reduced polymeric species and the corresponding neutral polymeric precursor indicates an organic group. The organic group may also be part of a polymer chain. It may also comprise; one or more heteroatoms, such as nitrogen, oxygen, sulfur, selenium, etc. For example, the meaning of the group N [symbol] is meant to include any trivalent nitrogen-containing organic group.

In one aspect of the invention, a surface modified electrode, suitable for use in devices, such as optoelectronic devices is provided. The surface modified electrode comprises at least one conductive layer and at least one reduced polymeric material. The reduced polymeric material comprises at least one additional electron relative to a corresponding neutral polymeric precursor. The reduced polymeric material is capable of enhancing the donation or transfer of a charge from one material to an adjacent material. In an embodiment, deposition of a reduced polymeric material on an electrode surface, like aluminum or ITO (indium tin oxide) reduces the work function of the electrode surface. Further, the reduced work function persists after air exposure, which allows for sufficient work time to use the coated electrode surface in building optoelectronic devices. In an embodiment, resistance to air-induced loss of work function of the electrode surface can be achieved using copolymer forms of the corresponding neutral polymeric precursors, such as for example, a styrene-vinylnaphthalene copolymer.

Suitable materials that can be used for the conductive layer include metals, metal oxides, or polymers that can conduct electrons. Examples of conductive metal oxides include the well-known indium tin oxide (ITO) and other related materials. Conductive polymers having a system of conjugated double bonds to facilitate conduction of electrons can also be used. A wide variety of such conductive polymers are known in the art. Preferred conductive layers include at least one metal, at least one metal oxide, or combinations thereof.

The reduced polymeric material is derived from the corresponding neutral polymeric precursor, wherein the neutral polymeric precursor is susceptible to accepting at least one electron from an electron donor to form an anionic species. In one embodiment, the neutral polymeric precursor comprises at least one aromatic radical. In an embodiment, the aromatic radicals may comprise pendant groups located on the polymer chain. In one embodiment, the reduced polymeric material is derived from a neutral polymeric precursor which has been subjected to reduction by a metallic species susceptible to giving up an electron. Potassium metal (K⁰) is a metal recognized by those skilled in the art as being susceptible to giving up an electron. In one embodiment, the neutral polymeric precursor can gives rise to the reduced polymeric material by an interaction of the neutral polymeric precursor with an atom or an ion of the metal. The term “interacting” or “interaction” means capturing, holding, stabilizing in place, or otherwise forming a bond with a metal atom or ion. In one embodiment, the neutral polymeric precursor is capable of sharing electrons with, and stabilizing, a reduced metal (a metal in a negative oxidation state), a metal in a zero oxidation state, or a metal ion (a metal in a positive oxidation state). In another embodiment, the neutral polymeric precursor is a polarizable or an ionizable moiety. In still another embodiment, the neutral polymeric precursor is capable of forming a complex with the metal atom or ion. Aromatic radicals, such as phenyl, phenylene, naphthyl, naphthylene, anthracenyl, and the like, are capable of accepting an electron from an electron donor metal species (atom or ion) to form a negatively charged radical anion species. The electron donor is usually a metal species, which after donating an electron to the neutral polymeric precursor remains and balances the charge or charges present in the reduced polymeric material. Whatever its source, the reduced polymeric material comprises at least one charge balancing cationic species. The cationic species may be a simple cation such as sodium ion (Na⁺) of may be a radical cation species, or a complex cation species. The cationic species present in the reduced polymeric material may also be generated from organic species, for example an organic species which is susceptible to giving up an electron to the neutral polymeric precursor thereby generating the reduced polymeric material and a radical cation. Non-limiting examples of organic species capable of forming radical cations in this manner include organic nitrogen compounds (e.g. tris(2,4,6-tribromophenyl)amine), and organic phosphorus compounds (e.g. tris(2,4,6-tribromophenyl)phosphine) which are transformed into nitrogen-centered and organic phosphorus-centered radical cations respectively. The radical anions can be further reduced to (i.e. the neutral polymeric precursor can also accept more than one electron to form an anionic species such as dianionic species, or a system comprising two or more radical anion moieties, or a system comprising a combination of one or more radical anion moieties and one or more dianion moieties. Non-limiting examples of electron donors include those selected from the group consisting of Group I metals and Group II metals, Group II metals, Group IV metals, scandium, yttrium, and the lanthanide series of metals. It should be understood that the names of the Groups of the Periodic Table, as used herein, are those designated by the International Union of Pure and Applied Chemistry (“IUPAC”). Specific examples of suitable electron donors include lithium, sodium, potassium, cesium, calcium, magnesium, indium, tin, zirconium, and aluminum.

The neutral polymeric precursor corresponding to the reduced polymeric material is generally a polymeric material comprising delocalized electrons, for example polymers comprising conjugated double bonds, polymers comprising conjugated triple bonds, and polymers comprising a combination of conjugated double and triple bonds. Frequently, the reduced polymeric material is conveniently prepared via the reduction of a neutral polymeric precursor comprising conjugated double bonds configured in one or more aromatic rings. While not wishing to be bound by any particular theory, it is believed that the reduced polymeric material functions as an electron transfer-promoting material that, in an embodiment, enhances electron injection from a cathode of an electronic device into an adjacent electronically active material. Electronically active materials are sometimes referred to as “electroluminescent materials”.

In one embodiment, the neutral polymeric precursor comprises structural units (I)

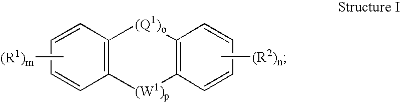

wherein R¹ and R² are independently at each occurrence a halogen atom, a C₁-C₂₀ aliphatic radical, a C₂-C₁₀ aromatic radical, a C₃-C₁₀ cycloaliphatic radical, a nitro group, or a cyano group. The variables “m” and “n” independently have values of 0 to 3 including the values 0 and 3. The variables “o” and “p” independently have values of 0 to 1 including 0 and 1. The sum of the values of the variables “o”+“p” is greater than 0. That is, not both “o” and “p” can be zero. W¹ is a moiety having a valency of at least 2, said moiety being selected from the group consisting of a bond, the group N [symbol] , an oxygen atom, a sulfur atom, a carbonyl group, the group C—R³, the group N—R³, and the group 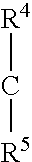
wherein R³, R⁴ and R⁵ are independently selected from the group consisting of a hydrogen atom, a halogen atom, a polymer chain, a C₁-C₂₀ aliphatic radical, a C₂-C₁₀ aromatic radical, and a C₃-C₁₀ cycloaliphatic radical. Q¹ is a bond, a carbonyl group, or the group 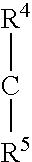
wherein R⁴ and R⁵ are independently selected from the group consisting of a hydrogen atom, a halogen atom, a polymer chain, a C₁-C₂₀ aliphatic radical, a C₂-C₁₀ aromatic radical, and a C₃-C₁₀ cycloaliphatic radical. The meaning of the group N [symbol] is meant to include any trivalent nitrogen-containing organic group. In one embodiment, the notation “N [symbol] ” denotes a trivalent nitrogen linked to a polymer chain (i.e. [symbol] ) having a number average molecular weight in excess of 5,000 grams per mole. In an embodiment, one or more of the organic groups on the nitrogen can comprise heteroatoms, such as nitrogen, oxygen, sulfur, and selenium. Examples of neutral polymeric precursors comprising structural units (I) include (N-polystryrenylcarbazole, a compound wherein “n” and “m” are zero, W¹ is a bond, and Q¹ is the group N—R³ wherein, R³ is a polymer chain comprising polystyrene. Additional examples of a neutral polymeric precursors comprising structural units (I) include poly(3-yinylanthracene) (m=1, R¹ is a C₂ trivalent aliphatic radical, n=0, Q¹=W¹=C—R³ wherein R³ is hydrogen), poly(9-methyl-9-vinylxanthene) (m=n=0, W¹ is an oxygen atom, Q¹ is R⁴—C—R⁵ wherein R⁴ a C₁-aliphatic radical (a methyl group) and R⁵ is a trivalent C₂ aliphatic radical (C₂H₃)), poly(3-ethynylanthracene), poly(3-ethynyl-9,9-dimethylxanthene), poly(3-vinyl-N-methylcarbazole), and the like.

In a second embodiment, the neutral polymeric precursor comprises structural units (II) 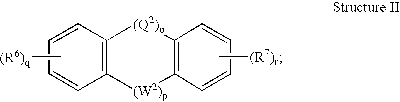
wherein R⁶ and R⁷ are independently at each occurrence a halogen atom, a C₁-C₂₀ aliphatic radical, a C₂-C₁₀ aromatic radical, a C₃-C₁₀ cycloaliphatic radical, a nitro group, a cyano group, or a polymer chain ( [symbol] ) The variables “q” and “r” independently have values of 0 to 4 inclusive of the values 0 and 4. The sum of the values of “q” and “r” (q+r) is greater than 0. The variables “o” and “p” independently have values of 0 to 1; wherein o+p is greater than 0. W² is is a moiety having a valency of at least 2, said moiety being selected from the group consisting of a bond, N [symbol] ; an oxygen atom, a sulfur atom, a carbonyl group, the group C—R³, the group N—R³, and the group 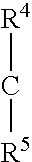
wherein R³, R⁴ and R⁵ are independently selected from the group consisting of a hydrogen atom, a halogen atom, a polymer chain, a C₁-C₂₀ aliphatic radical, a C₂-C₁₀ aromatic radical, and a C₃-C₁₀ cycloaliphatic radical. Q² is a bond, a carbonyl group, or a group selected from among 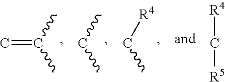
R⁴ and R⁵ are independently selected from the group consisting of a hydrogen atom, a halogen atom, a polymer chain, a C₁ —C₂₀ aliphatic radical, a C₂-C₁₀ aromatic radical, and a C₃-C₁₀ cycloaliphatic radical. Examples of neutral polymeric precursors comprising structural units (II) include polystyrene endcapped with 9,9-dimethylxanthene (“q”=1, “r”=0, R⁶ is a polymer chain composed of polystyrene, Q²=R⁴—C—R⁵ wherein R⁴═R⁵=a C₁-aliphatic radical (a methyl group)).

In a third embodiment, the neutral polymeric precursor comprises structural units (M) 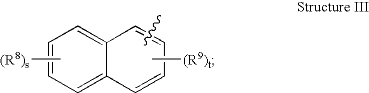
wherein R⁸ and R⁹ are independently at each occurrence a halogen atom, a C₁-C₂₀ aliphatic radical, a C₂-C₁₀ aromatic radical, a C₃-C₁₀ cycloaliphatic radical, a nitro group, or a cyano group; “s” has a value of 0 to 3; and “t” has a value of 0 to 4; and “o” and “p” independently have values of 0-1; wherein o+p is greater than 0. Examples of neutral polymeric precursors comprising structural units (III) include poly(1-vinylnapthalene), poly(2-vinylnapthalene), poly(2-vinylnapthalene-styrene) copolymer, and the like.

In a fourth embodiment, the neutral polymeric precursor comprises structural units (IV) 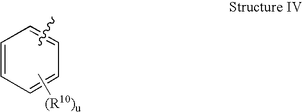
wherein R¹⁰ is independently at each occurrence a halogen atom, a C₁-C₂₀ aliphatic radical, a C₂-C₁₀ aromatic radical, a C₃-C₁₀ cycloaliphatic radical, a nitro group, or a cyano group; and “u” has a value of 0 to 5. Examples of neutral polymeric precursors comprising structural units (IV) include polystyrene, poly(4-chlorostyrene), poly(4-phenylstyrene), poly(3-phenylstyrene), and the like.

In a fifth embodiment, the neutral polymeric precursor comprises structural units (V)

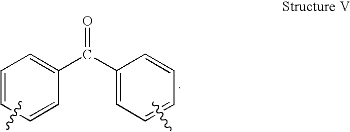

In a sixth embodiment, the neutral polymeric precursor comprises structural units (VI) 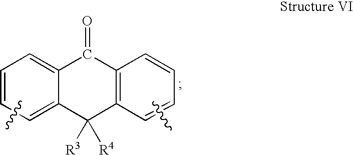
wherein R⁴ and R⁵ are independently a C₁-C₂₀ aliphatic radical, a C₂-C₁₀ aromatic radical, or a C₃-C₁₀ cycloaliphatic radical.

In a seventh embodiment, the neutral polymeric precursor comprises structural units (VII) 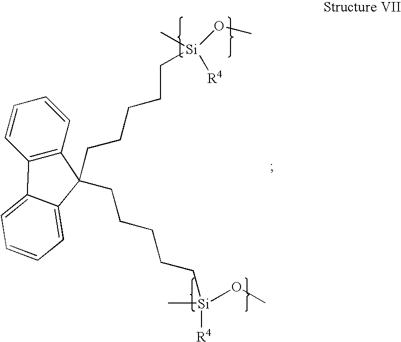
having siloxane repeat units, wherein R⁴ is independently at each occurrence a C₁-C₂₀ aliphatic radical, a C₂-C₁₀ aromatic radical, or a C₃-C₁₀ cycloaliphatic radical.

In an eighth embodiment, the neutral polymeric precursor comprises structural units (VIII) 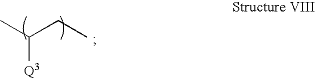
wherein Q³ is selected from the group consisting of a naphthyl group and a binaphthyl group. Examples of neutral polymeric precursors comprising structural units (VIII) include poly(3-vinyl-1,1′-binapthalene), poly(2-vinyl-1,1′binapthalene), poly(2-vinylnapthalene-styrene) copolymer, and the like.

In a ninth embodiment, the neutral polymeric precursor comprises structural units (IX) 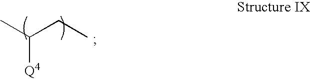
wherein Q⁴ is selected from the group consisting of a phenyl group and a biphenyl group. Examples of neutral polymeric precursors comprising structural units (IX) include poly(4-vinyl-1,1′-biphenyl), poly(3-vinyl-1,1′-biphenyl), and the like.

In other embodiments, the neutral polymeric precursor comprises structural units derived from at least one polymerizable monomer. Examples of suitable polymerizable monomers include, but are not limited to vinyl naphthalene, styrene, vinyl anthracene, vinyl pentacene, vinyl chrysene, vinyl carbazole, vinyl thiophene, vinyl pyridine, (1,4-diethynyl)aromatics, such as (1,4-diethynyl)benzene; and combinations of the foregoing polymerizable monomers. Further, the polymerizable monomer may comprise one or more crosslinkable groups, such as, for example, vinyl groups, allyl groups, styryl groups, and alkynyl groups. The aromatic radical may also comprise one or more heteroatoms, such as oxygen, sulfur, selenium, and nitrogen. Some examples of neutral polymeric precursors are poly(3-hexylthiophene-2,5-diyl), poly(fluorenyleneethynylene) polymers, such as those exemplified by structure X 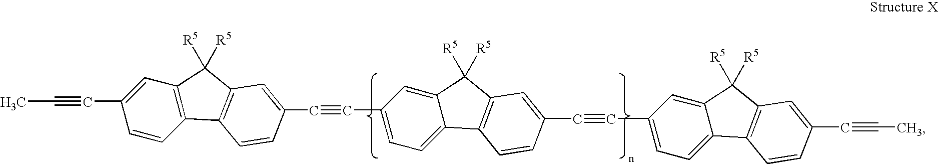
where R⁵ is a 2-ethylhexyl group; and poly(1,4-phenylenevinylene) polymers, such as for example, poly{([2-methoxy-5-(2′-ethylhexyloxy)]-1,4-phenylenevinylene}.

The neutral polymeric precursor may also comprise structural units derived from at at least one organosilicon hydride, wherein the organosilicon hydride comprises at least one Si—H bonds. When organosilicon hydrides containing more than one Si—H bond are used, such as organosilicon dihydrides and organosilicon trihydrides, cross-linked polymeric materials may result. In an embodiment, the neutral polymeric precursor comprises structural units derived from from at least one organosilicon hydride of structure XI, XII, or XIII

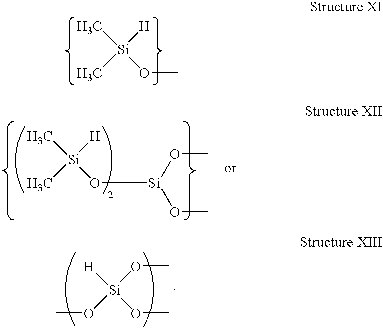

In a specific embodiment, the neutral polymeric precursor comprises structural units derived from at least one organosilicon hydride selected from the group consisting of CH₃)₂Si(H)O—[Si(CH₃)₂O]ₓ—Si(CH₃)₂(H), and (CH₃)₃SiO-[SiCH₃(H)O]_{x′}-[Si(CH₃)₂O]_{y′}—Si(CH₃)₃; wherein x′ and y′ independently have values from about 1 to about 30.

The reduced polymeric materials are preferably prepared by contacting the corresponding neutral polymeric precursor with a metal (such as an alkali metal, for example, potassium) or metal ion by reacting the metal or a metal halide (such as an alkali halide, for example potassium fluoride) in a suitable solvent, such as DME (1,2-dimethoxyethane), THF (tetrahydrofuran), DEE (ethyleneglycol diethylether), or xylenes. Solvent use may, in principle be avoided by contacting hot melts of the neutral polymeric precursors directly with the electron donor metal or metal salt. Thus in an embodiment of the present invention, a coating composition comprising at least one reduced polymeric material (as described previously) and at least one polar aprotic solvent can be applied as a coating on an electrode surface using techniques known in the art. The modified electrode thus obtained can be used in producing EL devices.

The reduced polymeric materials facilitate charge injection from an electron donor layer into an electronically active (or electroluminescent) material, thus facilitating the preparation of electronic display devices. In one embodiment, the reduced polymeric material can be incorporated into an electronic device to enhance the electron transport from or to an electrode. For example, an organic electroluminescent (“EL”) device can benefit from a reduced polymeric material of the present invention, such as one of the materials disclosed above, which material is disposed between the cathode and the organic electroluminescent material of the device. The organic EL material emits light when a voltage is applied across the electrodes. The reduced polymeric material can form a distinct interface with the organic EL material, or a continuous transition region having a composition changing from a substantially pure reduced polymeric material to a substantially pure organic EL material. In an embodiment, the reduced polymeric material can be deposited on an underlying material, such as an electrode surface, by a method selected from the group consisting of spin coating, spray coating, dip coating, roller coating, or ink-jet printing.

The anode of an organic EL device generally comprises a material having a high work function; e.g., greater than about 4.4 electron volts. Indium tin oxide (“ITO”) is typically used for this purpose since it is substantially transparent to light transmission and allows light emitted from organic EL layer easily to escape through the ITO anode layer without being significantly attenuated. The term “substantially transparent” means allowing at least 50 percent, preferably at least 80 percent, and more preferably at least 90 percent, of light in the visible wavelength range transmitted through a film having a thickness of about 0.5 micrometer, at an incident angle of less than or equal to 10 degrees. Other materials suitable for use as the anode layer are tin oxide, indium oxide, zinc oxide, indium zinc oxide, zinc indium tin oxide, antimony oxide, and mixtures thereof. The anode layer may be deposited on the underlying element by physical vapor deposition, chemical vapor deposition, or sputtering. The thickness of an anode comprising such an electrically conducting oxide can be in the range from about 10 nanometers to about 500 nanometers, in an embodiment, from about 10 nanometers to about 200 nanometers in another embodiment, and from about 50 nanometers to about 200 nanometers in still another embodiment. A thin, substantially transparent layer of a metal, for example, having a thickness of less than about 50 nanometers, can also be used as a suitable conducting layer. Suitable metals for anode are those having a high work function, such as greater than about 4.4 electron volts, for example, silver, copper, tungsten, nickel, cobalt, iron, selenium, germanium, gold, platinum, aluminum, or mixtures thereof or alloys thereof. In one embodiment, it may be desirable to dispose the anode on a substantially transparent substrate, such as one comprising glass or a polymeric material.

The cathode injects negative charge carriers (electrons) into the organic EL layer and is made of a material having a low work function; e.g., less than about 4 electron volts. In an embodiment, the low-work function materials suitable for use as a cathode are metals, such as K, Li, Na, Cs, Mg, Ca, Sr, Ba, Al, Ag, In, Sn, Zn, Zr, Sc, Y, elements of the lanthanide series, alloys thereof, or mixtures thereof. Suitable alloy materials for the manufacture of cathode layer are Ag—Mg, Al—Li, In—Mg, and Al—Ca alloys. Layered non-alloy structures are also possible, such as a thin layer of a metal such as calcium, or a non-metal, such as LiF, covered by a thicker layer of some other metal, such as aluminum or silver. The cathode may be deposited on the underlying element by physical vapor deposition, chemical vapor deposition, or sputtering. The Applicants unexpectedly discovered that a reduced polymeric material, chosen from among those disclosed above lowered the work function of cathode materials, thus reducing the barrier for electron injection and/or transport into organic EL material.

The organic EL layer serves as the transport medium for both holes and electrons. In this layer these excited species combine and drop to a lower energy level, concurrently emitting EM radiation in the visible range. Organic EL materials are chosen to electroluminesce in the desired wavelength range. The thickness of the organic EL layer is preferably kept in the range of about 100 nanometers to about 300 nanometers. The organic EL material may be a polymer, a copolymer, a mixture of polymers, or lower molecular-weight organic molecules having unsaturated bonds. Such materials possess a delocalized 1-electron system, which gives the polymer chains or organic molecules the ability to support positive and negative charge carriers with high mobility. Suitable EL polymers are poly(n-vinylcarbazole) (“PVK”, emitting violet-to-blue light in the wavelengths of about 380-500 nanometers) and its derivatives; polyfluorene and its derivatives such as poly(alkylfluorene), for example poly(9,9-dihexylfluorene) (410-550 nanometers), poly(dibctylfluorene) (wavelength at peak EL emission of 436 nanometers) or poly{9,9-bis(3,6-dioxaheptyl)-fluorene-2,7-diyl} (400-550 nanometers); poly(praraphenylene) (“PPP”) and its derivatives such as poly(2-decyloxy-1,4-phenylene) (400-550 nanometers) or poly(2,5-diheptyl-1,4-phenylene); poly(p-phenylene vinylene) (“PPV”) and its derivatives such as dialkoxy-substituted PPV and cyano-substituted PPV; polythiophene and its derivatives such as poly(3-alkylthiophene), poly(4,4′-dialkyl-2,2′-bithiophene), poly(2,5-thienylene vinylene); poly(pyridine vinylene) and its derivatives; polyquinoxaline and its derivatives; and polyquinoline and its derivatives. Mixtures of these polymers or copolymers based on one or more of these polymers and others may be used to tune the color of emitted light.

Another class of suitable EL polymers is the polysilanes. Polysilanes are linear silicon-backbone polymers substituted with a variety of alkyl and/or aryl side groups. They are quasi one-dimensional materials with delocalized sigma—conjugated electrons along polymer backbone chains. Examples of polysilanes are poly(di-n-butylsilane), poly(di-n-pentylsilane), poly(di-n-hexylsilane), poly(methylphenylsilane), and poly{bis(p-butylphenyl)silane} which are disclosed in H. Suzuki et al., “Near-Ultraviolet Electroluminescence From Polysilanes,” 331 Thin Solid Films 64-70 (1998). These polysilanes emit light having wavelengths in the range from about 320 nanometers to about 420 nanometers.

Organic materials having molecular weight less than, for example, about 5000 that are made of a large number of aromatic units are also applicable. An example of such materials is 1,3,5-tris {n-(4-diphenylaminophenyl) phenylamino}benzene, which emits light in the wavelength range of 380-500 nanometers. The organic EL layer also may be prepared from lower molecular weight organic molecules, such as phenylanthracene, tetraarylethene, coumarin, rubrene, tetraphenylbutadiene, anthracene, perylene, coronene, or their derivatives. These materials generally emit light having maximum wavelength of about 520 nanometers. Still other suitable materials are the low molecular-weight metal organic complexes such as aluminum-, gallium-, and indium-acetylacetonate, which emit light in the wavelength range of 415-457 nanometers, aluminum-(picolymethylketone)-bis{2,6-di(t-butyl)phenoxide} or scandium-(4-methoxy-picolylmethylketone)-bis(acetylacetonate), which emits in the range of 420-433 nanometers. For white light application, the preferred organic EL materials are those emit light in the blue-green wavelengths.

Other suitable organic EL materials that emit in the visible wavelength range are organometallic complexes of 8-hydroxyquinoline, such as tris(8-quinolinolato)aluminum and materials disclosed in U. Mitschke and P. Bauerle, “The Electroluminescence of Organic Materials,” J. Mater. Chem., Vol. 10, pp. 1471-1507 (2000).

More than one organic EL layer may be formed successively one on top of another, each layer comprising a different organic EL material that emits in a different wavelength range. Such a construction can facilitate a tuning of the color of the light emitted from the overall light-emitting device.

Furthermore, one or more additional layers may be included in the light-emitting device to further increase the efficiency of the EL device. For example, an additional layer can serve to improve the injection and/or transport of positive charges (holes) into the organic EL layer. The thickness of each of these layers is kept to below 500 nanometers, preferably below 100 nanometers. Suitable materials for these additional layers are low-to-intermediate molecular weight (for example, less than about 2000) organic molecules, poly(3,4-ethylenedioxythipohene) doped with polystyrene sulfonate acid (“PEDOT:PSS”), and polyaniline. They may be applied during the manufacture of the device by conventional methods such as spray coating, dip coating, or physical or chemical vapor deposition. In one embodiment of the present invention, a hole injection enhancement layer can be introduced between the anode layer and the organic EL layer to provide a higher injected current at a given forward bias and/or a higher maximum current before the failure of the device. Thus, the hole injection enhancement layer facilitates the injection of holes from the anode. Suitable materials for the hole injection enhancement layer are arylene-based compounds disclosed in U.S. Pat. No. 5,998,803; such as 3,4,9,10-perylenetetra-carboxylic dianhydride or bis(1,2,5-thiadiazolo)-p-quinobis(1,3-dithiole).

The light-emitting device may further include a hole transport layer disposed between the hole injection enhancement layer and the organic EL layer. The hole transport layer transports holes and blocks the transportation of electrons so that holes and electrons are optimally combined in the organic EL layer. Exemplary materials suitable for the hole transport layer include triaryldiamine, tetraphenyldiamine, aromatic tertiary amines, hydrazone derivatives, carbazole derivatives, triazole derivatives, imidazole derivatives, oxadiazole derivatives having an amino group, and polythiophenes as disclosed in U.S. Pat. No. 6,023,371.

In other embodiments, the light-emitting device may further include an “electron injecting and transporting enhancement layer” as an additional layer, which can be disposed between the electron-donating material and the organic EL layer. Materials suitable for the electron injecting and transporting enhancement layer are metal organic complexes such as tris(8-quinolinolato)aluminum, oxadiazole derivatives, perylene derivatives, pyridine derivatives, pyrimidine derivatives, quinoline derivatives, quinoxaline derivatives, diphenylquinone derivatives, and nitro-substituted fluorene derivatives, as disclosed in U.S. Pat. No. 6,023,371.

The light-emitting device can further comprise one or more photoluminescent (“PL”) layers. Such PL layers absorb a portion of light emitted by the organic EL layer and convert it to light having different wavelengths, thus providing the ability to tune the color of light emitted by the overall device. PL materials can be of an organic or inorganic type.

Organic PL materials typically have rigid molecular structure and are extended π-systems. They typically have small Stokes shifts and high quantum efficiency. For example, organic PL materials that exhibit absorption maxima in the blue portion of the spectrum exhibit emission in the green portion of the spectrum. Similarly, those that exhibit absorption maxima in the green portion of the spectrum exhibit emission the yellow or orange portion of the spectrum. Such small Stokes shifts give the organic PL materials high quantum efficiencies.

Suitable classes of organic PL materials are the perylenes and benzopyrenes, coumarin dyes, polymethine dyes, xanthene dyes, oxobenzanthracene dyes, and perylenebis(dicarboximide) dyes disclosed by Tang et al. in U.S. Pat. No. 4,769,292 which is incorporated herein by reference. Other suitable organic PL materials are the pyrans and thiopyrans disclosed by Tang et al. in U.S. Pat. No. 5,294,870 which is incorporated herein by reference. Still other suitable organic PL materials belong to the class of azo dyes, such as those described in P. F. Gordon and P. Gregory, “Organic Chemistry in Colour,” Springer-Verlag, Berlin, pp. 95-108 (1983). Preferred organic PL materials are those that absorb a portion of the green light emitted by the light-emitting member and emit in the yellow-to-red wavelengths of the visible spectrum. Such emission from these organic PL materials coupled with the portion of unabsorbed light from the light-emitting member produces light that is close to the black-body radiation locus.

Inorganic PL materials (also sometimes referred to as “phosphors”) may be disposed adjacent to the organic PL layer, or may also be disposed between the anode layer and the organic PL layer. The particle size and the interaction between the surface of the particle and the polymeric medium used to form the layer determine how well particles are dispersed in the polymeric medium to form the inorganic PL layer. Many micrometer-sized particles of oxide materials, such as zirconia, yttrium and rare-earth garnets, and halophosphates, disperse well in standard silicone polymers, such as poly(dimethylsiloxanes) by simple stirring. If necessary, other dispersant aids, such as a surfactant or a polymeric material like poly(vinyl alcohol) may be used to suspend many standard phosphors in solution. The phosphor particles may be prepared from larger pieces of phosphor material by any grinding or pulverization method, such as ball milling using zirconia-toughened balls or jet milling. They also may be prepared by crystal growth from solution, and their size may be controlled by terminating the crystal growth at an appropriate time. The preferred phosphor materials efficiently absorb electromagnetic (EM) radiation emitted by the organic EL material and re-emit light in another spectral region. Such a combination of the organic EL material and the phosphor allows for a flexibility in tuning the color of light emitted by the light-emitting device. A particular phosphor material or a mixture of phosphors may be chosen to emit a desired color or a range of color to complement the color emitted by the organic EL material and that emitted by the organic PL materials. An exemplary phosphor is the cerium-doped yttrium aluminum oxide Y₃Al₅O₁₂ garnet (“YAG:Ce”). Other suitable phosphors are based on YAG doped with more than one type of rare earth ions, such as (Y_{1-x-y}GdₓCe_{y})₃Al₅O₁₂ (“YAG:Gd,Ce”), (Y₁₋ₓCeₓ)₃(Al_{1-y}Ga_{y})O₁₂ (“YAG:Ga,Ce”), (Y_{1-x-y}GdₓCe_{y})₃(Al_{5-z}Ga_{z})O₁₂ (“YAG:Gd,Ga,Ce”), and (Gd_{1-y}Ceₓ)Sc₂Al₃O₁₂ (“GSAG”) where 0≦x≦1, 0≦y≦1, 0≦z≦5 and x+y≦1. For example, the YAG:Gd,Ce phosphor shows an absorption of light in the wavelength range from about 390 nm to about 530 nm (i.e., the blue-green spectral region) and an emission of light in the wavelength range from about 490 nm to about 700 nm (i.e., the green-to-red spectral region). Related phosphors include Lu₃Al₅O₁₂ and Tb₂Al₅O₁₂, both doped with cerium. In addition, these cerium-doped garnet phosphors may also be additionally doped with small amounts of Pr (such as about 0.1-2 mole percent) to produce an additional enhancement of red emission. The following are examples of phosphors that are efficiently excited by EM radiation emitted in the wavelength region of 300 nm to about 500 nm by polysilanes and their derivatives.

Non-limiting examples of green light-emitting phosphors are Ca₈Mg(SiO₄)₄Cl₂:Eu²⁺, Mn²⁺; GdBO₃:Ce³⁺, Tb³⁺; CeMgAl₁₁O₁₉: Tb^{3+; Y}₂SiO₅:Ce³⁺, Tb³⁺; and BaMg₂Al₁₆O₂₇:Eu³⁺, Mn ²⁺. Non-limiting examples of red light-emitting phosphors are Y₂O₃:Bi³⁺,Eu³⁺; Sr₂P₂O₇:Eu²⁺,Mn²⁺; SrMgP₂O₇:Eu²⁺,Mn²⁺; (Y,Gd)(V,B)O₄:Eu³⁺; and 3.5MgO.0.5MgF₂.GeO₂: Mn⁴⁺ (magnesium fluorogermanate). Non-limiting examples of blue light-emitting phosphors are BaMg₂Al₁₆O₂₇:Eu²⁺; Sr₅(PO₄)₁₀Cl₂:Eu²⁺; and (Ba,Ca,Sr)₅(PO₄)₁₀(Cl,F)₂:Eu²⁺, (Ca,Ba,Sr)(Al,Ga)₂S₄:Eu²⁺. Non-limiting examples of yellow light-emitting phosphors are (Ba,Ca,Sr)₅(PO₄)₁₀(Cl,F)₂:Eu²⁺,Mn²⁺.

Still other ions may be incorporated into the phosphor to transfer energy from the light emitted from the organic EL material to other activator ions in the phosphor host lattice as a way to increase the energy utilization. For example, when Sb³⁺ and Mn²⁺ ions exist in the same phosphor lattice, Sb³⁺ efficiently absorbs light in the blue region, which is not absorbed very efficiently by Mn²⁺, and transfers the energy to Mn²⁺ ion. Thus, a larger total amount of light emitted by the organic EL material is absorbed by both ions, resulting in higher quantum efficiency of the total device.

The phosphor particles are dispersed in a film-forming polymeric material, such as polyacrylates, substantially transparent silicone or epoxy. A phosphor composition of less than about 30, preferably less than about 10, percent by volume of the mixture of the film-forming polymeric material and phosphor is used. A solvent may be added into the mixture to adjust the viscosity of the film-forming material to a desired level. The mixture of the film-forming material and phosphor particles is formed into a layer by spray coating, dip coating, printing, or casting on a substrate.

Another type of opto-electronic devices, which can benefit from an efficient transport of electrons across an interface between an electrode and an adjacent EL-active material, are photovoltaic (“PV”) cells.

The surface modified electrode produced as described earlier in this disclosure are valuable for forming electrooptic devices, which in an embodiment comprises a surface modified first electrode; a second eletrode; and an electroluminescent organic material disposed between the first electrode and the second electrode; wherein the surface modified first electrode comprises at least one conductive layer, and at least one reduced polymeric material, said reduced polymeric material comprising at least one additional electron relative to a corresponding neutral polymeric precursor; and at least one cationic species. In an embodiment, at least one of the first or second electrode may be transparent. The transparent electrode may have a percent light transmission of greater than or equal to about 90 percent in an embodiment, and greater than or equal to 95 percent in another embodiment.

The electrooptic devices can be prepared by a method comprising: (a) providing a surface-modified first electrode (prepared as described previously in this disclosure); (b) disposing on the surface-modified first electrode a charge transfer-promoting material; (c) disposing on the charge transfer-promoting material an EL organic material; and (d) providing a second electrode on the electronically active material.

### EXAMPLES

The following examples are set forth to provide those of ordinary skill in the art with a detailed description of how the methods claimed herein are evaluated, and are not intended to limit the scope of what the inventors regard as their invention. Unless indicated otherwise, parts are by weight, temperature is in ° C.

The unit for CPD is volt (V), and the unit for effective work function is electron volt (eV). Generally, the greater the CPD, the lower the effective work function.

### Example 1

This Example demonstrates the use of a styrene-vinylnaphthalene copolymer (abbreviated as “Naphstyr”) in preparing a reduced polymeric material which reduced the work function of aluminum electrode surface by 0.66 electron volts.

A 1:1 copolymer of styrene and vinylnaphthalene was prepared in toluene using AIBN (azobis(isobutyronitrile) initiator. The polymer was isolated by precipitation into methanol, then purified by two precipitations from a methanol/methylene chloride solvent system. Gel permeation chromatography analysis showed the polymer to have a number average molecular weight (Mₙ) of 7679, a weight average molecular weight (M_{w}) of 13,900, and a M_{w}/Mₙ of 1.8.

The copolymer was dissolved in ethyleneglycol dimethyl ether (DME) and reacted with two equivalents of potassium under conditions at which the DME was maintained at reflux. A dark solution of Naphstyr-K was obtained. The solution was spin coated (at 4000 revolutions per minute) onto Al-glass in a glove box. Kelvin probe analysis of the Al/Naphstyr-K showed a contact potential difference (CPD) of 1.76 volts. The CPD of Al-glass is 1.1 volts, thus giving a lowering of effective work function of 0.66 eV. After being exposed for about 1 minute, the CPD was measured again, and was found to be unchanged at 1.76 volts.

### Example 2

The procedure of Example 1 was repeated, except that the spin coating of the Naphthstyr-K solution in DME was done at 1000 revolutions per minute. Initial Kelvin probe measurement of the surface modified electrode showed a work function value of 1.82 V. After being exposed to air for about 1 minute, the Kelvin probe value was unchanged. The surface modified electrode was left exposed to ambient air overnight. Kelvin probe measurement carried out on the next day showed a CPD value of 1.38 V, which was still 0.2 volt higher that (1.18 volts) of the Al-glass control sample, indicating a reduction in effective work function of 0.2 electron volt.

### Example 3

This Example demonstrates the use of poly(vinylnaphthalene) in preparing a reduced polymeric material which reduced the effective work function of aluminum electrode surface by 0.42 electron volts.

Poly(vinylnaphthalene) was prepared by free-radical polymerization with AIBN initiator in toluene. The product was purified by two precipitations from methanol/methylene chloride solvent mixture. The purified polymer had a M_{w} of 9230, a Mₙ of 4332, and a M_{w}/Mₙ of 2.13.

Potassium reduction of polyvinylnaphthalene in THF gave a dark solution. This material (K-polyNaph) was spin coated onto Al/glass in the glove box. Kelvin probe analysis showed a work function of 1.53 V (versus 1.11 V for the control Al-glass). After a 1-minute air exposure, Kelvin probe showed a CPD value of 1.48 volts. After exposure to air for 24 hours, the Kelvin probe showed a CPD value of 1.21 volts.

The results from Examples 1-3 shows that the reduced polymeric material comprising reduced phenyl and/or naphthyl pendant groups imparts a lower work function and some resistance to re-oxidation by air.

### Example 4

Commercial polyvinyl carbazole (PVK) was dissolved in THF and then reduced with potassium to give a dark blue solution. The K—PVK solution was spin coated onto Al/glass. Kelvin probe analysis showed a CPD value of 1.42 V.

### Example 5

This Example demonstrates the synthesis of a neutral polymeric precursor prepared by reaction of 9,9-di(5-hexenyl)fluorene with M(D^{H})₄D₁₅M [Me₃SiO—(MeSiHO)₄—(SiMe₂—O)₁₅—OsiMe₃].

Fluorene (5 grams, 30.1 millimoles), and -bromo-5-hexene (15.7 grams, 64 millimoles) were combined with 50 milliliters of dimethyl sulfoxide (DMSO) and 50 milliliters of 50 percent aqueous sodium hydroxide solution, and heated to about 120° C. for 14 hours. After being cooled to ambient temperature, the reaction mixture contained three layers, which were separated using a separatory funnel. The top-most layer was yellow, the middle layer was pink and the bottom layer was milky white. The bottom layer was removed, and the two top organic layers were washed with saturated sodium chloride solution. Addition of the aqueous sodium chloride solution caused loss of the pink color. A yellow organic layer resulted, which was separated and subjected to vacuum distillation to remove DMSO and un-reacted n-hexyl bromide. GC analysis of the residual material in the distillation flask showed it to be a mixture of greater than 90 weight percent of 9,9-di(5-hexenyl)fluorene and less than 10 weight percent of 9-(5-hexenyl)fluorene, respectively. Complete consumption of fluorene was also deduced. The assay of the desired product by gas chromatography and proton NMR analysis showed it to be composed of 92 percent of 9,9-di(5-hexenyl)fluorene.

### Example 6

This Example describes the preparation of a hydrosilylation product corresponding to a 1:2 relative mole ratio of olefin groups of 9,9-di(5-hexenyl)fluorene and Si—H groups of M(D^{H})₄D₁₅M, respectively.

A solution of 9,9-di(5-hexenyl)fluorene (0.124 gram, 0.376 millimole) was prepared in DME (5 milliliters). A 1 milliliter portion of this solution was combined with GE Silicones intermediates 88405 (having formula M(D^{H})₄D₁₅M, 0.12 gram) and Karstedt's platinum catalyst (1 microliter of a 5 weight percent solution in xylenes) to obtain a Si—H/olefin mole ratio of 2:1, respectively. The hydrosilylation reaction was followed by proton NMR spectroscopy. After heating at 80° C. for 1 hour, spectral analysis showed complete consumption of all the olefin groups. The resulting product was the desired cross-linked hydrosilylated product.

### Example 7

This Example describes the preparation of a hydrosilylation product corresponding to a 1:1 relative mole ratio of olefin groups of 9,9-di(5-hexenyl)fluorene and M(D^{H})₄D₁₅M, respectively.

A solution of 9,9-di(5-hexenyl)fluorene (0.124 gram, 0.376 millimole) was prepared in DME (5 milliliters). A 1 milliliter portion of this solution was combined with GE Silicones intermediates 88405 (having formula M(D^{H})₄D₁₅M, 0.06 gram) and Karstedt's platinum catalyst (1 microliter of a 5 weight percent solution in xylenes) to obtain a Si—H groups/olefin groups mole ratio of 1:1, respectively. The hydrosilylation reaction was followed by proton NMR spectroscopy. After heating at 80° C. for 1 hour, spectral analysis showed complete consumption of all the olefin groups. The resulting product was the desired cross-linked hydrosilylated product.

### Example 8

This Example describes the preparation of the reduced polymeric material derived from the neutral polymeric precursor (whose preparation is described in Example 7).

A blue solution of potassium-9,9-di(n-hexyl5-hexenyl)fluorene, prepared as described below in Example 11 (1 milliliter DME solution) was added to a vial that contained 1 microliter of the Karstedt platinum catalyst solution as described above. This solution was then added to a second vial that contained M(D^{H})₄D₁₅M (0.058 gram). The blue color changed to red after addition to M(D^{H})₄D₁₅M polymer containing Si—H bonds. The combined solution was then spin coated onto Al-glass at 4000 revolutions per minute in a dry box. The slide was then heated at 90° C. for 1 hour. Kelvin probe analysis showed a CPD value 1.45 V. The slide was then exposed to air for about 1 minute. The new CPD value after air exposure was 1.26 V, still about 0.3 V volts higher (or equivalently, 0.3 electron volts reduction in effective work function) compared to that of the Al control measured prior to the coating. Finally, the film-coated slide was subjected to a Scotch Tape pull test, and then the CPD value was measured again. The CPD value remained unchanged at 1.26 V.

The results from Example 8 taken together with those shown in the Examples 12 and 13 (described below) demonstrates that the coating of the cross-linked organosilicon reduced polymeric species has good adhesion to the aluminum surface even after being heated to 90° C.

### Examples 9 and 10

Sodium benzophenone ketyl and potassium benzophenone ketyl were prepared by treatment of benzophenone (0.1 gram) with two molar equivalents of sodium and potassium, respectively, and stirring at ambient temperature for about 1 hour. The resulting solutions were spin coated on Al-glass to produce the corresponding surface-modified electrodes. CPD measurements showed that both modified electrodes had lower work functions relative to Al-glass. Thus, the CPD value for the sodium benzophenone ketyl coated electrode was 1.34 V. However, after air exposure for about 1 minute, the CPD decreased immediately to 1.006 V, compared to the 1.18 eV value observed for the control Al-glass. Similarly, the CPD value for potassium benzophenone ketyl coated electrode was 1.87 V, but brief exposure to air caused this value to rise to 1.2 V, almost the same as the CPD of the control sample.

### Example 11

This Example illustrates the results obtained with coating Al-glass sample with a coating solution containing potassium-9,9-di(n-hexenyl)fluorene.

In a Schlenk flask, 9,9-di(n-hexyl)fluorene (0.12 gram, 0.36 millimole), prepared as described in Example 5 was dissolved in 5 milliliters of dry DME and then potassium (0.034 gram, 0.87 millimole) was added. The mixture was then subjected to three freeze—degas-thaw cycles, and then stirred at ambient temperature. The solution turned blue within 45 min. The blue solution was spin coated onto Al/glass in a glove box at 4000 rpm (revolutions per minute). Kelvin probe measurement of blank Al/glass had a CPD (contact potential difference) value of 0.87 V. The Al/glass piece coated with the blue solution had a CPD value of 1.76 V, or a lowering of the effective work function by over 0.8 electron volts

### Example 12

A solution of DME with M(D^{H})₄D₁₅M and platinum catalyst was spin coated onto Al/glass at 4000 rpm and then heated at 90° C. for 1 hour. The CPD value was 0.98 V.

### Example 13

A DME solution of 9,9-di(n-hexyl)fluorene, platinum catalyst and M(D^{H})₄D₁₅M was spin-coated and heated as before. The CPD value was 1.13 V.

Examples 9-13 demonstrate that improvements in the electrode work function can be achieved even when the reduced organic material used to modify the electrode is not polymeric.

The invention has been described in detail with particular reference to preferred embodiments thereof, but it will be understood by those skilled in the art that variations and modifications can be effected within the spirit and scope of the invention.

What is claimed is:

1. A surface modified electrode comprising:
(a) at least one conductive layer; and
(b) at least one reduced polymeric material, said reduced polymeric material comprising at least one additional electron relative to a corresponding neutral polymeric precursor and at least one cationic species.

2. The surface modified electrode according to claim 1, wherein said corresponding neutral polymeric precursor comprises at least one aromatic radical.

3. The surface modified electrode according to of claim 2, wherein said corresponding neutral polymeric precursor comprises structural units (I) 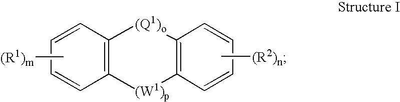
wherein R¹ and R² are independently at each occurrence a halogen atom, a C₁-C₂₀ aliphatic radical, a C₂-C₁₀ aromatic radical, a C₃-C₁₀ cycloaliphatic radical, a nitro group, or a cyano group; “m” and “n” independently have values of 0 to 3; “o” and “p” independently have values of 0 to 1; wherein o+p is greater than 0; W¹ is a moiety having a valency of at least 2, said moiety being selected from the group consisting of a bond, the group N [symbol] ; an oxygen atom, a sulfur atom, a carbonyl group, the group C—R³, the group N—R³, and the group 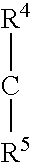
wherein R³, R⁴ and R⁵ are independently selected from the group consisting of a hydrogen atom, a halogen atom, a polymer chain, a C₁-C₂₀ aliphatic radical, a C₂-C₁₀ aromatic radical, and a C₃-C₁₀ cycloaliphatic radical; and
Q¹ is a bond, a carbonyl group, or the group 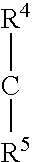
wherein R⁴ and R⁵ are independently selected from the group consisting of a hydrogen atom, a halogen atom, a polymer chain, a C₁-C₂₀ aliphatic radical, a C₂-C₁₀ aromatic radical, and a C₃-C₁₀ cycloaliphatic radical.

4. The surface modified electrode according to of claim 3, wherein said corresponding neutral polymeric precursor comprises structural units (II) 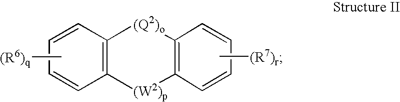
wherein R⁶ and R⁷ are independently at each occurrence a halogen atom, a C₁-C₂₀ aliphatic radical, a C₂-C₁₀ aromatic radical, a C₃-C₁₀ cycloaliphatic radical, a nitro group, a cyano group, or a polymer chain; “q” and “r” independently have values of 0 to 4; wherein q+r is greater than 0; “o” and “p” independently have values of 0 to 1; wherein o+p is greater than 0; W² is is a moiety having a valency of at least 2, said moiety being selected from the group consisting of a bond, N [symbol] ; an oxygen atom, a sulfur atom, a carbonyl group, the group C—R³, the group N—R³, and the group 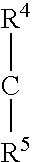
wherein R³, R⁴ and R⁵ are independently selected from the group consisting of a hydrogen atom, a halogen atom, a polymer chain, a C₁-C₂₀ aliphatic radical, a C₂-C₁₀ aromatic radical, and a C₃-C₁₀ cycloaliphatic radical; and
Q² is a bond, a carbonyl group, or a group selected from among 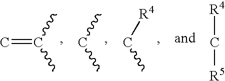
R⁴ and R⁵ are independently selected from the group consisting of a hydrogen atom, a halogen atom, a polymer chain, a C₁-C₂₀ aliphatic radical, a C₂-C₁₀ aromatic radical, and a C₃-C₁₀ cycloaliphatic radical.

5. The surface modified electrode according to of claim 2, wherein said corresponding neutral polymeric precursor comprises structural units (III) 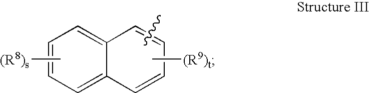
wherein R⁸ and R⁹ are independently at each occurrence a halogen atom, a C₁-C₂₀ aliphatic radical, a C₂-C₁₀ aromatic radical, a C₃-C₁₀ cycloaliphatic radical, a nitro group, or a cyano group; “s” has a value of 0 to 3; and “t” has a value of 0 to 4.

6. The surface modified electrode according to of claim 2, wherein said corresponding neutral polymeric precursor comprises structural units (IV) 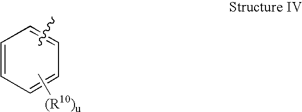
wherein R¹⁰ is independently at each occurrence a halogen atom, a C₁-C₂₀ aliphatic radical, a C₂-C₁₀ aromatic radical, a C₃-C₁₀ cycloaliphatic radical, a nitro group, or a cyano group; and “u” has a value of 0 to 5.

7. The surface modified electrode according to of claim 2, wherein said corresponding neutral polymeric precursor comprises structural units (V)

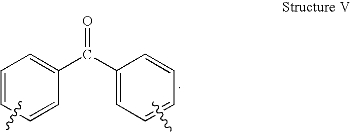

8. The surface modified electrode according to of claim 2, wherein said corresponding neutral polymeric precursor comprises structural units (VI) 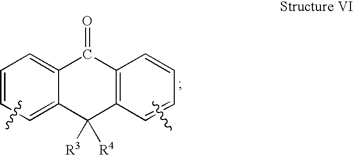
wherein R⁴ and R⁵ are independently a C₁-C₂₀ aliphatic radical, a C₂-C₁₀ aromatic radical, or a C₃-C₁₀ cycloaliphatic radical.

9. The surface modified electrode according to claim 2, wherein said corresponding neutral polymeric precursor comprises structural units (VII) 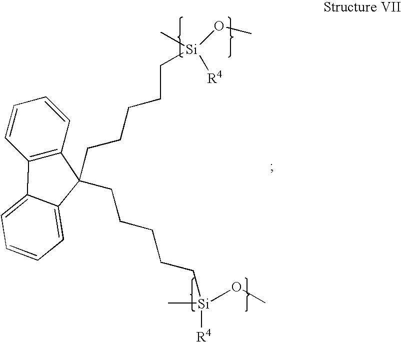
having siloxane repeat units, wherein R⁴ is independently at each occurrence a C₁-C₂₀ aliphatic radical, a C₂-C₁₀ aromatic radical, or a C₃-C₁₀ cycloaliphatic radical.

10. The surface modified electrode according to claim 2, wherein said corresponding neutral polymeric precursor comprises structural units (VIII) 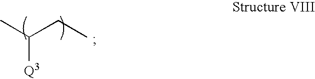
wherein Q³ is selected from the group consisting of a naphthyl group and a binaphthyl group.

11. The surface modified electrode according to claim 2, wherein said corresponding neutral polymeric precursor comprises structural units (IX) 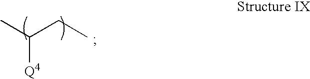
wherein Q⁴ is selected from the group consisting of a phenyl group and a biphenyl group.

12. The surface modified electrode according to claim 2, wherein said corresponding neutral polymeric precursor comprises structural units derived from at least one polymerizable monomer selected from the group consisting of vinyl naphthalene, styrene, vinyl anthracene, vinyl pentacene, vinyl chrysene, vinyl carbazole, vinyl thiophene, vinyl pyidine, (1,4-diethynyl)benzene, and combinations of the foregoing polymerizable monomers.

13. The surface modified electrode according to claim 12, wherein said at least one polymerizable monomer further comprises one or more crosslinkable groups selected from the group consisting of vinyl groups, allyl groups, styryl groups, and alkynyl groups.

14. The surface modified electrode according to claim 2, wherein said corresponding neutral polymeric precursor is selected from the group consisting of poly(3-hexylthiophene-2,5-diyl), poly(fluorenyleneethynylene), poly{([2-methoxy-5-(2′-ethylhexyloxy)]-1,4-phenylenevinylene}.

15. The surface modified electrode according to claim 2, wherein said corresponding neutral polymeric precursor comprises structural units derived from from at least one organosilicon hydride, wherein the organosilicon hydride comprises at least one Si—H bond.

16. The surface modified electrode according to claim 15, wherein said at least one organosilicon hydride comprises structural units selected from the group consisting of structures X, XI, and XII

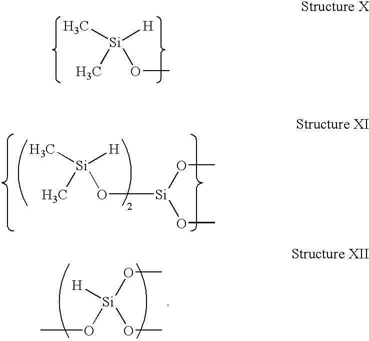

17. The surface modified electrode according to claim 15, wherein said at least one organosilicon hydride is selected from the group consisting of CH₃)₂Si(H)O—[Si(CH₃)₂O]ₓ—Si(CH₃)₂(H), and (CH₃)₃SiO—[SiCH₃(H)O]_{x′}—[Si(CH₃)₂O]_{y′}—Si(CH₃)₃; wherein x, x′ and y independently have values from about 1 to about 30.

18. The surface modified electrode according to claim 1, wherein said at least one reduced polymeric material comprises at least one radical anion species.

19. The surface modified electrode according to claim 1, wherein said at least one reduced polymeric material comprises at least one dianion species.

20. The surface modified electrode according to claim 1, wherein said at least one cationic species is selected from the group consisting of cations of Group I metals, Group II metals, Group III metals, Group IV metals, and mixtures thereof.

21. The surface modified electrode according to claim 1, wherein said at least one cationic species is selected from the group consisting of metal cations of lithium, sodium, potassium, cesium, calcium, magnesium, indium, tin, zirconium, aluminum, cesium, and mixtures thereof.

22. A coating composition comprising:
(a) at least one reduced polymeric material, said reduced polymeric material comprising at least one additional electron relative to a corresponding neutral polymeric precursor, said reduced polymeric material comprising at least one cationic species; and
(b) at least one polar aprotic solvent.

23. An electrooptic device comprising:
(a) a surface modified first electrode;
(b) a second eletrode; and
(c) an electroluminescent organic material disposed between said first electrode and said second electrode;
wherein said surface modified first electrode comprises at least one conductive layer, and at least one reduced polymeric material, said reduced polymeric material comprising at least one additional electron relative to a corresponding neutral polymeric precursor and at least one cationic species.

24. The electrooptic device of claim 23, wherein at least one of said first or second electrode is transparent.

25. A surface modified electrode comprising:
(a) at least one conductive layer; and
(b) at least one reduced organic material, said reduced organic material comprising at least one additional electron relative to a corresponding neutral polymeric precursor and at least one cationic species.

26. The surface modified electrode of claim 25 wherein said reduced organic material is selected from the group consisting of sodium benzophenone ketyl, postassium benzophenone ketyl, and potassium-9,9-di(n-hexenyl)fluorene.
